(19) United States
(12) Patent Application Publication
(10) Pub. No.: US 2025/0245405 A1
(43) Pub. Date: Jul. 31, 2025

(54) Upscaling Rock or Fluid Properties of a Hydrocarbon Reservoir from Well Sample Scale to Borehole Scale

(71) Applicant: Saudi Arabian Oil Company, Dhahran (SA)

(72) Inventor: Fatai A. Anifowose, Al-Khobar (SA)

(21) Appl. No.: 18/425,242

(22) Filed: Jan. 29, 2024

(51) Int. Cl. G06F 30/28

(52) U.S. Cl. CPC G06F 30/28

(57) ABSTRACT

Example methods and systems for upscaling rock or fluid properties of a hydrocarbon reservoir from well sample scale to borehole scale are disclosed. One example method includes obtaining one or more wireline logs of a well interval in a hydrocarbon reservoir. A trained machine learning (ML) model is applied to the one or more wireline logs to upscale one or more rock or fluid properties of the hydrocarbon reservoir to a borehole scale, where the trained ML model includes a set of weight factors, and applying the trained ML model to the one or more wireline logs includes applying the set of weight factors to the one or more wireline logs to determine the one or more rock or fluid properties at the borehole scale. The determined one or more rock or fluid properties is provided to determine a volume of the hydrocarbon reservoir for exploration of the hydrocarbon reservoir.

### TECHNICAL FIELD

The present disclosure relates to computer-implemented methods and systems for upscaling rock or fluid properties of a hydrocarbon reservoir from well sample scale to borehole scale.

### BACKGROUND

Hydrocarbon reservoir rock or fluid properties can generally be obtained from core, plug, or thin section samples that are analyzed in a laboratory using specialized equipment and that are generally at nanometer or micrometer scales. In contrast, reservoir evaluation workflows are generally performed using data at the borehole scale. To integrate the borehole scale data with the ground-truth data obtained from the analysis of the core, plug, and/or thin section samples for reservoir characterization, the core, plug, and/or thin section samples can be upscaled from nanometer or micrometer scale to borehole scale.

### SUMMARY

The present disclosure involves methods and systems for upscaling rock or fluid properties of a hydrocarbon reservoir from well sample scale to borehole scale. One example method includes obtaining one or more wireline logs of a well interval in a hydrocarbon reservoir. A trained machine learning (ML) model is applied to the one or more wireline logs to upscale one or more rock or fluid properties of the hydrocarbon reservoir to a borehole scale, where the trained ML model includes a set of weight factors, and applying the trained ML model to the one or more wireline logs includes applying the set of weight factors to the one or more wireline logs to determine the one or more rock or fluid properties at the borehole scale. The determined one or more rock or fluid properties is provided to determine a volume of the hydrocarbon reservoir for exploration of the hydrocarbon reservoir.

The previously described implementation is implementable using a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium. These and other embodiments may each optionally include one or more of the following features.

In some implementations, the one or more wireline logs include at least one of gamma ray (GR) log, neutron porosity (NPHI) log, density (RHOB) log, spontaneous potential (SP) log, resistivity (RES) log, sonic compression (DTC) log, or sonic shear (DTS) log.

In some implementations, the one or more rock or fluid properties include at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.

In some implementations, the well interval is an unsampled well interval.

In some implementations, multiple wireline logs of multiple wells is obtained; multiple reservoir rock or fluid property measurements is obtained from samples of the multiple wells; and the trained ML model is determined by training a machine learning model using the multiple wireline logs and the multiple reservoir rock or fluid property measurements.

In some implementations, the samples of the multiple wells include at least one of core samples, plug samples, or thin section samples of the multiple wells.

In some implementations, determining the trained ML model includes determining multiple learning parameters in the machine learning model.

In some implementations, the multiple learning parameters include at least one of a learning rate, a quantity of neurons, an activation function, or the set of weight factors.

In some implementations, the activation function is a sigmoid function or a Gaussian function.

In some implementations, the trained ML model includes an artificial neural network (ANN), a support vector machine (SVM), a regression tree (RT), a random forest (RF), an extreme learning machine (ELM), or a type I and type II fuzzy logic (T1FL/T2FL).

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates example relationships among different scales of core, plug, and thin section samples taken from a well in a hydrocarbon reservoir, according to some implementations.

FIG. 2 illustrates an example comparison between the result of upscaling a core measurement porosity to borehole scale using linear interpolation and the result of using learning-based upscaling, according to some implementations.

FIG. 3 illustrates an example workflow for upscaling reservoir rock and/or fluid properties using a machine learning model, according to some implementations.

FIG. 4 illustrates an example workflow of training a machine learning model and using the trained machine learning model to predict upscaled reservoir rock and/or fluid properties, according to some implementations.

FIG. 5 illustrates example results of predicting upscaled values of cementation factor using three ML methods, according to some implementations.

FIG. 6 illustrates an example process for upscaling rock or fluid properties of a hydrocarbon reservoir from well sample scale to borehole scale, according to some implementations.

FIG. 7 is a block diagram of an example computer system that can be used to provide computational functionalities associated with described algorithms, methods, functions, processes, flows, and procedures, according to some implementations.

FIG. 8 illustrates hydrocarbon production operations that include both one or more field operations and one or more computational operations, which exchange information and control exploration for the production of hydrocarbons, according to some implementations.

Like reference numbers and designations in the various drawings indicate like elements.

### DETAILED DESCRIPTION

This disclosure describes systems and methods that use a learning-based methodology to establish a highly nonlinear relationship between the measurements at the lower (core/plug/thin section) scale and their corresponding parameters at the higher (borehole) scale to predict the reservoir property values at the gaps between the measurements. The disclosed methods can lead to more realistic results as they can capture the geological patterns embedded in the available data.

The disclosed methods can be applied to any rock or fluid properties that are obtained from core, plug, and/or thin section samples, for example, cementation factor (the exponent m in Archie equation), porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, and/or diagenetic facies.

For example, the cementation factor can indicate reduction in the number and size of pore openings or reduction in the closed-off (dead-end) channels in rock samples. The cementation factor can model how much the pore network increases the resistivity. The cementation factor has a negative relationship with rock permeability. In some cases, the numerical value of cementation factor can be obtained from experiments on plug samples from cored wells. Because of the cost and intensive labor associated with obtaining the measurement, in some cases only a few measurements of cementation factors are available in a well. As a result of this, the measurements of cementation factor are very scanty and sparse. A number of values of cementation factors have been observed for certain lithological settings, for example, 1.3 for unconsolidated sands, between 1.8 and 2.0 for consolidated sandstones, and between 1.7 and 4.1 in carbonate rocks. Because of the sparsity of cementation factor measurements and the challenge in upscaling cementation factor measurements, in some cases the cementation factor is assumed to be 2.0 in carbonate reservoir analysis and evaluation. This assumption can lead to underestimation or overestimation of reservoir volumes.

In some cases, the cementation factor can be related to wireline logs in a multivariate fashion. A suite of common archival wireline logs, for example, gamma ray (GR), neutron porosity (NPHI), density (RHOB), spontaneous potential (SP), resistivity (RES), sonic compression (DTC), and sonic shear (DTS), gathered from several wells, can be labeled with their corresponding historical cementation factor measurements to form a training database that can be used to train a machine learning model. The machine learning model can then be used to generate a set of high-resolution cementation factor values for an entire well or reservoir interval of interest at the borehole scale, given a set of wireline logs for that well or interval. The aforementioned machine learning model based method applies whether the new well or interval is cored or not, i.e., the new well or interval can have some or no cementation factor measurements at all.

The disclosed systems and methods provide many advantages over existing systems. As one example, the disclosed methods can preserve geological heterogeneity of a reservoir while upscaling the reservoir rock and/or fluid properties from core, plug, or thin section scale to borehole scale. As another example, the disclosed methods can speed up the process of reservoir evaluation once a machine learning model is trained using data from different wells and used to upscale reservoir rock and/or fluid properties to borehole scale.

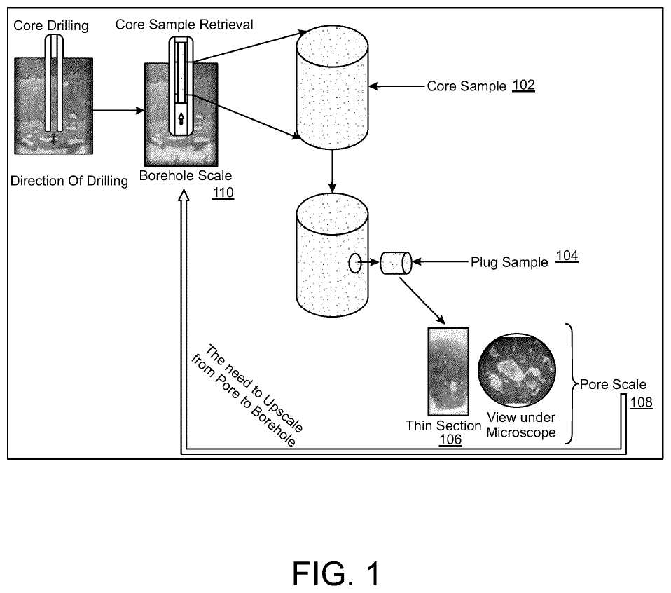

FIG. 1 illustrates example relationships among different scales of core sample 102, plug sample 104, and thin section sample 106 taken from a well in a hydrocarbon reservoir. Table 1 shows the different types of analysis that can be performed on the samples and the types of data that can be obtained from each analysis. In some cases, since the samples are taken at certain intervals or within specific zones of interest of the well, the data obtained from the samples are scanty and sparse within the well. Reservoir evaluation workflows are generally performed at the borehole scale 110 using data in different resolutions, for example, wireline logs data are in half-foot resolution, drilling parameters and mud gas data are in one-foot resolution, and mud logging/cuttings lithology data are in 10 feet resolution. To integrate these borehole scale data with the ground-truth data obtained from the analysis of the core, plug, and/or thin section samples, the core, plug, and/or thin section samples can be upscaled from well sample scale (e.g., pore scale 108, at nanometer or micrometer) to borehole scale 110.

TABLE 1

| Sample | Type of Analysis | Examples of Rock/Fluid Properties produced |
|---|---|---|
| Core | Routine Core Analysis | Porosity, permeability, grain density, core photographs, CT |
| | | scans, gas-oil ratio (GOR), API, core gamma. |
| Plug | Special Core Analysis | Capillary pressure, relative permeability, wettability, nuclear |
| | | magnetic resonance, electrical properties (cementation factor, |
| | | saturation index, and tortuosity), acoustic properties, |
| | | geomechanical properties, clay mineralogy (XRD, XRF, ICM- |
| | | MS) |
| Thin | Thin Section Analysis | Textural analysis (grain size, grain morphology, grain |
| Section | | distribution, rock typing, mineralogy), structural analysis (pore |
| | | distribution, pore typing, sedimentary structure, depositional |
| | | environment, diagenetic facies). |

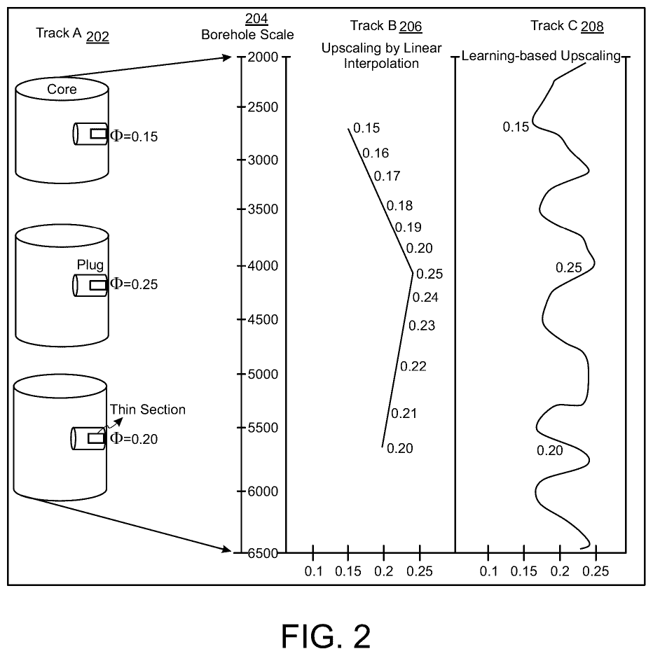

FIG. 2 illustrates an example comparison between the result of upscaling a core measurement porosity (q) (Track A 202) to borehole scale 204 (Track B 206) using linear interpolation and the result of using learning-based upscaling (Track C 208). Track A 202 shows discrete porosity measurements at well sample scale. The discrete porosity measurements of track A 202 are upscaled to borehole scale 204. Track B 206 shows upscaling of track A 202 by linear interpolation. Track C 208 shows learning-based upscaling of track A 202. The learning-based upscaling is better than the linear interpolation-based upscaling because porosity measurements from other wells used to train a machine learning model that is subsequently used in learning-based upscaling can provide additional information for upscaling porosity measurements in track A 202 to borehole scale 204.

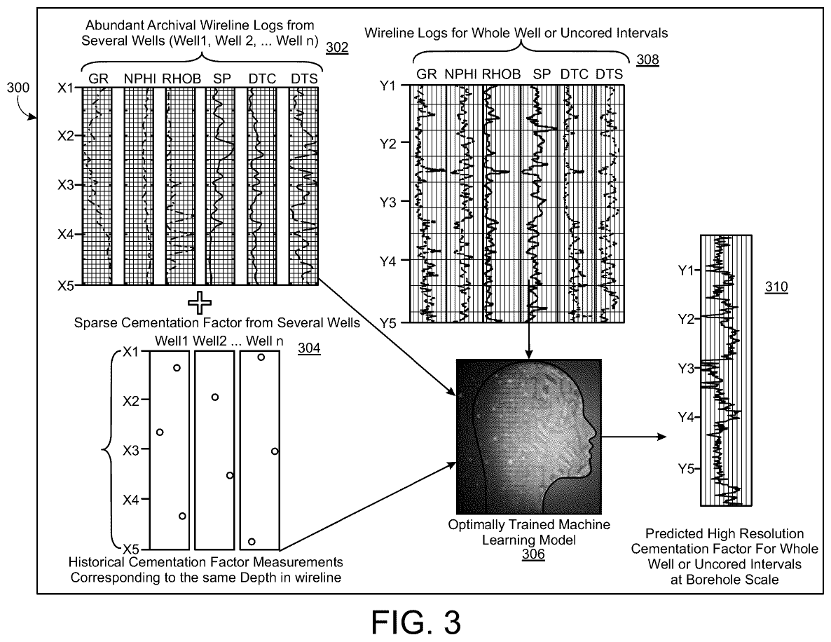

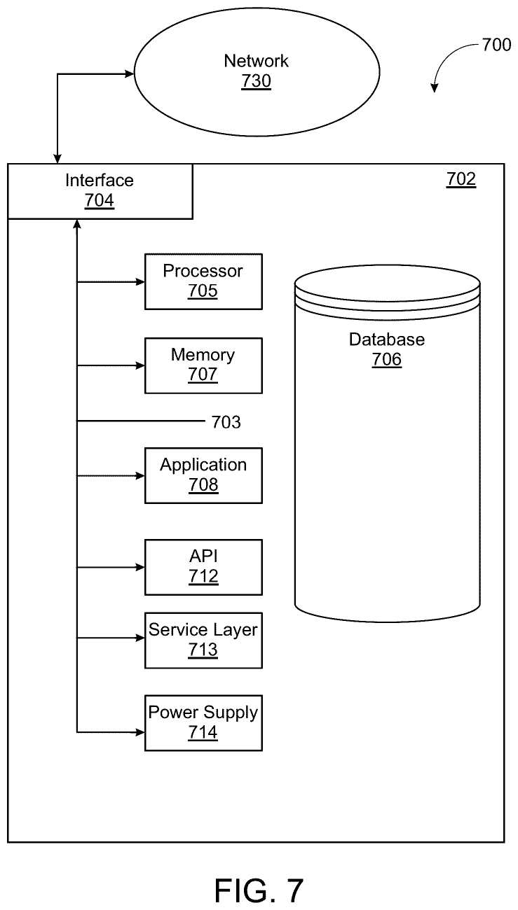

FIG. 3 illustrates an example workflow 300 for upscaling reservoir rock and/or fluid properties using a machine learning model. The example reservoir rock and/or fluid property upscaled in workflow 300 is cementation factor. Workflow 300 can also be used to upscale other reservoir rock and/or fluid properties, for example, the reservoir rock and/or fluid properties mentioned earlier. For convenience, workflow 300 will be described as being performed by a computer system having one or more computers located in one or more locations and programmed appropriately in accordance with this specification. An example of the computer system is the computer system 700 illustrated in FIG. 7.

At 302, a computer system obtains archival wireline logs data from one or more wells in a hydrocarbon reservoir.

At 304, the computer system obtains cementation factor measurements measured on plug samples from the one or more wells.

At 306, the computer system combines the wireline logs data from 302 with their corresponding cementation factor measurements from 304 to form a database to train a machine learning model. Table 2 shows an example that combines the cementation factor measurements for a well with their corresponding wireline logs data. The computer system can use the database to train and optimize the parameters of the machine learning model by creating a nonlinear function to fit the cementation factor measurements from 304 and the wireline logs data from 302.

TABLE 2

| | | | | | | | | Cementation |
|---|---|---|---|---|---|---|---|---|
| | Wireline Logs | | | | | | | Factor |
| Depth | GR | NPHI | RHOB | SP | RES | DTC | DTS | m |
| 2750 | 60 | 0.12 | 2.3 | 85 | 15000 | 10 | 12 | 1.50 |
| 4175 | 75 | 0.25 | 1.7 | 200 | 7500 | 14.5 | 11.2 | 2.70 |
| 5650 | 110 | 0.2 | 2.7 | 750 | 200 | 4.5 | 11.2 | 3.20 |
| . . . | . . . | . . . | . . . | . . . | . . . | . . . | . . . | . . . |
| . | . | . | . | . | . | . | . | . |
| . | . | . | . | . | . | . | . | . |
| . | . | . | . | . | . | . | . | . |

At 308, the computer system obtains new wireline logs data for a new well or a new reservoir interval of interest. The new well or the new reservoir interval of interest can be uncored and/or unsampled.

At 310, the computer system applies the trained machine learning model from 306 to the new wireline logs data from 308 to predict the cementation factor for the new well or a new reservoir interval of interest. Table 3 shows an extension of Table 2 to include the missing/unsampled points between the sampled points in Table 2.

TABLE 3

| | Wireline Logs | | | | | | | |
|---|---|---|---|---|---|---|---|---|
| Depth | GR | NPHI | RHOB | SP | RES | DTC | DTS | m |
| 2000 | 20 | 0.07 | 2.7 | 450 | 250 | 3.5 | 4.5 | ? |
| 2000.5 | 25 | 0.10 | 2.5 | 160 | 10000 | 4.5 | 10.5 | ? |
| 2001 | 15 | 0.17 | 2.1 | 200 | 17500 | 14.5 | 10.7 | ? |
| . | . | . | . | . | . | . | . | ? |
| . | . | . | . | . | . | . | . | |
| . | . | . | . | . | . | . | . | |
| 2750 | 60 | 0.12 | 2.3 | 85 | 15000 | 10 | 12 | 1.50 |
| 2750.5 | 20 | 0.07 | 2.7 | 450 | 250 | 3.5 | 4.5 | ? |
| 2752 | 25 | 0.10 | 2.5 | 160 | 10000 | 4.5 | 10.5 | ? |
| 2752.5 | 15 | 0.17 | 2.1 | 200 | 17500 | 14.5 | 10.7 | ? |
| . | . | . | . | . | . | . | . | ? |
| . | . | . | . | . | . | . | . | |
| . | . | . | . | . | . | . | . | |
| 4175 | 75 | 0.25 | 1.7 | 200 | 7500 | 14.5 | 11.2 | 2.70 |
| 4175.5 | 20 | 0.07 | 2.7 | 450 | 250 | 3.5 | 4.5 | ? |
| 4176 | 25 | 0.10 | 2.5 | 160 | 10000 | 4.5 | 10.5 | ? |
| 4176.5 | 15 | 0.17 | 2.1 | 200 | 17500 | 14.5 | 10.7 | ? |
| . | . | . | . | . | . | . | . | ? |
| . | . | . | . | . | . | . | . | |
| . | . | . | . | . | . | . | . | |
| 5650 | 110 | 0.2 | 2.7 | 750 | 200 | 4.5 | 11.2 | 3.20 |
| 5650.5 | 20 | 0.07 | 2.7 | 450 | 250 | 3.5 | 4.5 | ? |
| 5651 | 25 | 0.10 | 2.5 | 160 | 10000 | 4.5 | 10.5 | ? |
| 5651.5 | 15 | 0.17 | 2.1 | 200 | 17500 | 14.5 | 10.7 | ? |
| . | . | . | . | . | . | . | . | ? |
| . | . | . | . | . | . | . | . | |
| . | . | . | . | . | . | . | . | |
| 5998 | 110 | 0.2 | 2.7 | 750 | 200 | 4.5 | 11.2 | ? |
| 5998.5 | 20 | 0.07 | 2.7 | 450 | 250 | 3.5 | 4.5 | ? |
| 5999 | 25 | 0.10 | 2.5 | 160 | 10000 | 4.5 | 10.5 | ? |
| 5999.5 | 15 | 0.17 | 2.1 | 200 | 17500 | 14.5 | 10.7 | ? |
| 6500 | 100 | 0.21 | 1.8 | 95 | 2000 | 7.5 | 4.5 | ? |

In some implementations, the predicted cementation factor from 310 can then be used to estimate water saturation and subsequently the reservoir volume. For example, water saturation (S_{w}) can be calculated using the Archie equation by plugging the predicted cementation factor from 310 into the m exponent, among other inputs. An example equation used to calculate S_{w} is:

$${S}_{w} = {( \frac{{aR}_{w}}{{R}_{t} {ϕ}^{m}} )}^{1 / n}$$

where S_{w} equals water saturation, Rₜ equals total resistivity as measured by the resistivity logs, ϕ^{m} equals total porosity, C_{w}, the conductivity of the formation water, is defined by 1/R_{w}, m=cementation factor, and n=saturation exponent.

An example volumetric method to estimate reservoir volume is:

$$OOIP = \frac{7758 A h ϕ ( 1 - {S}_{w} )}{{B}_{o i}}$$

where A is the productive acreage of the reservoir, in acres, h is the height or thickness of the pay zone, ϕ is porosity, S_{w} is the water saturation, and Bₒᵢ is the original formation volume factor. The estimated reservoir volume can be used in reservoir exploration.

Workflow 300 illustrated in FIG. 3 is based on the machine learning methodology that utilizes the wireline log data in the sampled interval of a well and cementation factors corresponding to the wireline log data measured from core/plug samples of the well. Since no relationship had previously been established between wireline log data and cementation factor measurements before 306 in FIG. 3, machine learning (ML) models (e.g., artificial neural networks, support vector machine, decision tree, random forest, or multivariate linear regression) can be used to establish a nonlinear relationship between the wireline log data and reservoir rock and/or fluid properties such as cementation factor. For example, the machine learning model can be an artificial neural network (ANN), the ANN model can be configured and optimized with one or more hidden layers (depending on the volume and complexity of the training database), a sigmoid activation function in the hidden layer, a linear function in the summation layer, and training algorithms based on the Levenberg-Marquardt and Bayesian regulation backpropagation. An integrated training dataset, for example, the dataset from 306, can be used to train the ANN model.

In some implementations, for an unsampled interval of a well, the wireline logs data in the unsampled interval can be passed to the trained machine learning model, for example, the trained ANN model as input, thereby predicting the cementation factor of the unsampled interval at the borehole scale as the output/target variable. The predicted cementation factor data at the borehole scale can then be used in the volumetric analysis of the reservoir that includes the unsampled interval of the well.

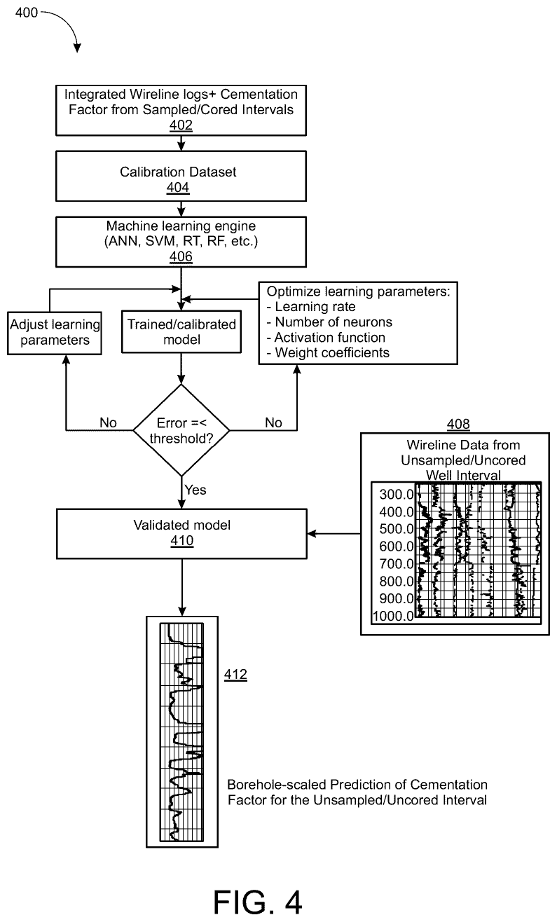

FIG. 4 illustrates an example workflow 400 of training a machine learning model and using the trained machine learning model to predict upscaled reservoir rock and/or fluid properties. The example reservoir rock and/or fluid property upscaled in workflow 400 is cementation factor. Workflow 400 can also be used to upscale other reservoir rock and/or fluid properties, for example, the reservoir rock and/or fluid properties mentioned earlier. For convenience, workflow 400 will be described as being performed by a computer system having one or more computers located in one or more locations and programmed appropriately in accordance with this specification. An example of the computer system is the computer system 700 illustrated in FIG. 7.

In some implementations, the ML model in workflow 400 can be any of the available machine learning models, for example, Artificial Neural Networks (ANN), Support Vector Machines (SVM), Regression Tree (RT), Random Forest (RF), Extreme Learning Machine (ELM), or Type I and Type II Fuzzy Logic (TIFL/T2FL). Using ANN as an example of the machine learning model in workflow 400, the combined wireline logs data and cementation factor data 402 for a sampled interval of a well can be used to form calibration dataset 404 that can be used to build and optimize ML engine 406. In some cases, calibration dataset 404 can be split into a training subset and a validation subset, for example, according to a 7:3 ratio.

In some implementations, the optimization/training process of machine learning engine 406 involves adjusting learning parameters of machine learning engine 406, for example, the learning rate, number of neurons, activation function, and weight coefficients, such that the error between the model predicted cementation factor and the actual values of cementation factor are kept within a pre-sct threshold. An example of a pre-set threshold is a mean squared error (MSE) of 0.05. If the error is within the pre-set threshold, machine learning engine 406 with the adjusted learning parameters becomes validated model 410 and can receive the wireline logs data 408 from an unsampled well interval to predict the cementation factor for the unsampled well interval. If the error is above the pre-set threshold, control of the optimization/training process goes back to re-adjust the learning parameters. In some cases, this process of matching the model prediction with the actual training and validation data can be called a feed-forward process. The process of re-adjusting the learning parameters to increase the match and reduce the error between the model prediction and the actual validation measurements can be called a back-propagation process. In some implementations, these feed-forward and back-propagation processes can have the capability to remove the bias embedded in the cementation factor measurements. This optimization/training process can continue until the error comes within the pre-set threshold or a pre-determined maximum number of iterations is reached. The best model achieved up to the end of the optimization/training process can be used for predicting upscaled reservoir rock and/or fluid properties, for example, upscaled prediction 412 of cementation factor. In some cases, the goal of the training and validation of machine learning engine 406 is to avoid under- and over-fitting of machine learning engine 406.

In some implementations, the training subset and the validation subset can be used to create in machine learning engine 406 a nonlinear relationship between the wireline logs data and the reservoir rock and/or fluid property data, for example, the cementation factor data. The nonlinear relationship can be created by multiplying each wireline log parameter by a weight factor determined by an activation function. This weight factor, generally ranging from 0 to +1, can be obtained from the degree of nonlinearity in the mapping between the wireline logs data and the cementation factor data. The weighting process can determine the effect a wireline log has on the overall nonlinear relationship. A function, f, such as a sigmoid, can be used to transform the input space to a high-dimensional nonlinear space to match the nature of the subsurface data. The nonlinear relationship can be as shown in a simplified form below:

$$Y = f ( {a}_{1} {X}_{1} + {a}_{2} {X}_{2} + … + {a}_{6} {X}_{6} )$$

where Y is the target variable (e.g., upscaled prediction of cementation factor data), a1, . . . , a6 are the weighting factors, X1, . . . , X6 are examples of the input wireline logs data, and f is the activation function such as Gaussian or sigmoid.

An example Gaussian function is in the form below:

$$f ( x ) = {e}^{- {x}^{2}}$$

where x is each of the input wireline logs.

An example sigmoid function is in the form below:

$$f ( x ) = \frac{1}{1 + {e}^{- x}}$$

where x is each of the input wireline logs.

In some implementations, another process in training validated model 410 is model re-calibration. In some implementations, when new or additional data (e.g., wireline logs and their corresponding cementation factor data from newly analyzed rock samples of a well interval) are available, they can be added to the existing calibration dataset 404. With the updated calibrated database, the same set of learning parameters may no longer be sufficient to fit validated model 410 to the newly updated calibration dataset 404. Therefore, new sets of the learning parameters of validated model 410 may be derived through the optimization and feedforward/back-propagation cycle to establish a good fit between the updated wireline logs data and the new set of cementation factor data.

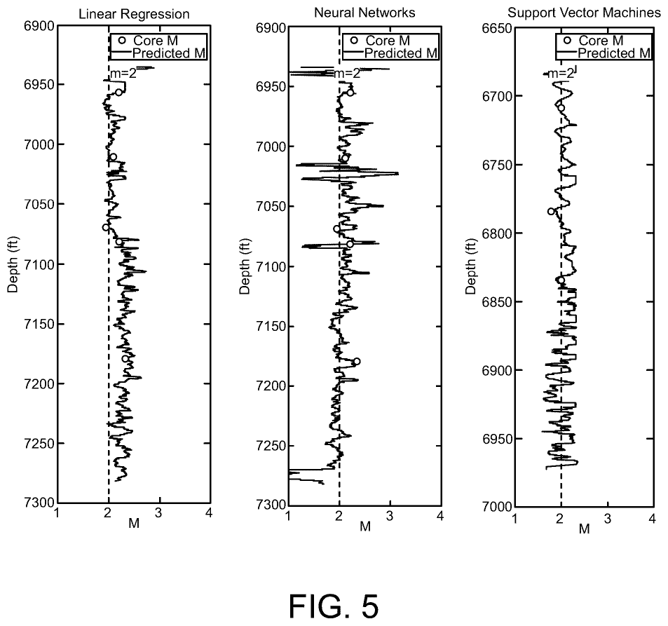

FIG. 5 illustrates example results of predicting upscaled values of cementation factor using three ML methods.

In some implementations, the upscaled prediction 412 of cementation factor can be used as one of the inputs to estimate water saturation, which in turn can be used to assess the volume of a reservoir.

Using upscaled prediction 412 of cementation factor can be more realistic and can produce more accurate reservoir volumetric assessment than using a constant value such as 2.0 (for a carbonate rock) or simply taking the average value or linearly interpolated set of values of cementation factor.

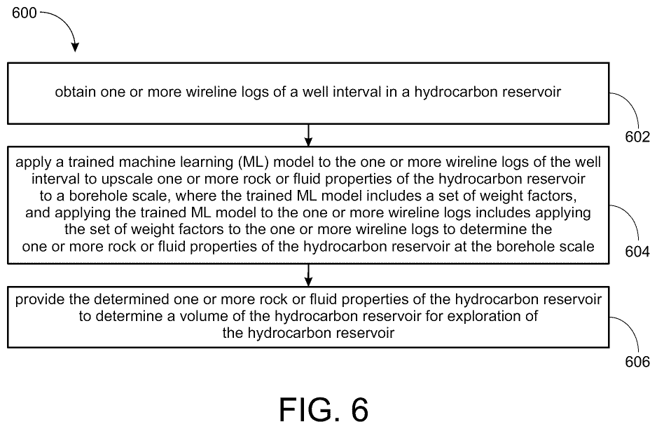

FIG. 6 illustrates an example process 600 for upscaling rock or fluid properties of a hydrocarbon reservoir from well sample scale to borehole scale. For convenience, process 600 will be described as being performed by a computer system having one or more computers located in one or more locations and programmed appropriately in accordance with this specification. An example of the computer system is the computer system 700 illustrated in FIG. 7.

At 602, a computer system obtains one or more wireline logs of a well interval in a hydrocarbon reservoir.

At 604, the computer system applies a trained machine learning (ML) model to the one or more wireline logs of the well interval to upscale one or more rock or fluid properties of the hydrocarbon reservoir to a borehole scale, where the trained ML model includes a set of weight factors, and applying the trained ML model to the one or more wireline logs includes applying the set of weight factors to the one or more wireline logs to determine the one or more rock or fluid properties of the hydrocarbon reservoir at the borehole scale.

At 606, the computer system provides the determined one or more rock or fluid properties of the hydrocarbon reservoir to determine a volume of the hydrocarbon reservoir for exploration of the hydrocarbon reservoir.

FIG. 7 is a block diagram of an example computer system 700 that can be used to provide computational functionalities associated with described algorithms, methods, functions, processes, flows, and procedures, according to some implementations of the present disclosure. In some implementations, the computer system performing workflow 300 or 400 can be the computer system 700, include the computer system 700, or the computer system performing workflow 300 or 400 can communicate with the computer system 700.

The illustrated computer 702 is intended to encompass any computing device such as a server, a desktop computer, an embedded computer, a laptop/notebook computer, a wireless data port, a smart phone, a personal data assistant (PDA), a tablet computing device, or one or more processors within these devices, including physical instances, virtual instances, or both. The computer 702 can include input devices such as keypads, keyboards, and touch screens that can accept user information. Also, the computer 702 can include output devices that can convey information associated with the operation of the computer 702. The information can include digital data, visual data, audio information, or a combination of information. The information can be presented in a graphical user interface (UI) (or GUI). In some implementations, the inputs and outputs include display ports (such as DVI-I+2× display ports), USB 3.0, GbE ports, isolated DI/O, SATA-III (6.0 Gb/s) ports, mPCIe slots, a combination of these, or other ports. In instances of an edge gateway, the computer 702 can include a Smart Embedded Management Agent (SEMA), such as a built-in ADLINK SEMA 2.2, and a video sync technology, such as Quick Sync Video technology supported by ADLINK MSDK+. In some examples, the computer 702 can include the MXE-5400 Series processor-based fanless embedded computer by ADLINK, though the computer 702 can take other forms or include other components.

The computer 702 can serve in a role as a client, a network component, a server, a database, a persistency, or components of a computer system for performing the subject matter described in the present disclosure. The illustrated computer 702 is communicably coupled with a network 730. In some implementations, one or more components of the computer 702 can be configured to operate within different environments, including cloud-computing-based environments, local environments, global environments, and combinations of environments.

At a high level, the computer 702 is an electronic computing device operable to receive, transmit, process, store, and manage data and information associated with the described subject matter. According to some implementations, the computer 702 can also include, or be communicably coupled with, an application server, an email server, a web server, a caching server, a streaming data server, or a combination of servers.

The computer 702 can receive requests over network 730 from a client application (for example, executing on another computer 702). The computer 702 can respond to the received requests by processing the received requests using software applications. Requests can also be sent to the computer 702 from internal users (for example, from a command console), external (or third) parties, automated applications, entities, individuals, systems, and computers.

Each of the components of the computer 702 can communicate using a system bus 703. In some implementations, any or all of the components of the computer 702, including hardware or software components, can interface with each other or the interface 704 (or a combination of both), over the system bus. Interfaces can use an application programming interface (API) 712, a service layer 713, or a combination of the API 712 and service layer 713. The API 712 can include specifications for routines, data structures, and object classes. The API 712 can be either computer-language independent or dependent. The API 712 can refer to a complete interface, a single function, or a set of APIs 712.

The service layer 713 can provide software services to the computer 702 and other components (whether illustrated or not) that are communicably coupled to the computer 702. The functionality of the computer 702 can be accessible for all service consumers using this service layer 713. Software services, such as those provided by the service layer 713, can provide reusable, defined functionalities through a defined interface. For example, the interface can be software written in JAVA, C++, or a language providing data in extensible markup language (XML) format. While illustrated as an integrated component of the computer 702, in alternative implementations, the API 712 or the service layer 713 can be stand-alone components in relation to other components of the computer 702 and other components communicably coupled to the computer 702. Moreover, any or all parts of the API 712 or the service layer 713 can be implemented as child or sub-modules of another software module, enterprise application, or hardware module without departing from the scope of the present disclosure.

The computer 702 can include an interface 704. Although illustrated as a single interface 704 in FIG. 7, two or more interfaces 704 can be used according to particular needs, desires, or particular implementations of the computer 702 and the described functionality. The interface 704 can be used by the computer 702 for communicating with other systems that are connected to the network 730 (whether illustrated or not) in a distributed environment. Generally, the interface 704 can include, or be implemented using, logic encoded in software or hardware (or a combination of software and hardware) operable to communicate with the network 730. More specifically, the interface 704 can include software supporting one or more communication protocols associated with communications. As such, the network 730 or the interface's hardware can be operable to communicate physical signals within and outside of the illustrated computer 702.

The computer 702 includes a processor 705. Although illustrated as a single processor 705 in FIG. 7, two or more processors 705 can be used according to particular needs, desires, or particular implementations of the computer 702 and the described functionality. Generally, the processor 705 can execute instructions and manipulate data to perform the operations of the computer 702, including operations using algorithms, methods, functions, processes, flows, and procedures as described in the present disclosure.

The computer 702 can also include a database 706 that can hold data for the computer 702 and other components connected to the network 730 (whether illustrated or not). For example, database 706 can be an in-memory, conventional, or a database storing data consistent with the present disclosure. In some implementations, the database 706 can be a combination of two or more different database types (for example, hybrid in-memory and conventional databases) according to particular needs, desires, or particular implementations of the computer 702 and the described functionality. Although illustrated as a single database 706 in FIG. 7, two or more databases (of the same, different, or combination of types) can be used according to particular needs, desires, or particular implementations of the computer 702 and the described functionality. While database 706 is illustrated as an internal component of the computer 702, in alternative implementations, database 706 can be external to the computer 702.

The computer 702 also includes a memory 707 that can hold data for the computer 702 or a combination of components connected to the network 730 (whether illustrated or not). Memory 707 can store any data consistent with the present disclosure. In some implementations, memory 707 can be a combination of two or more different types of memory (for example, a combination of semiconductor and magnetic storage) according to particular needs, desires, or particular implementations of the computer 702 and the described functionality. Although illustrated as a single memory 707 in FIG. 7, two or more memories 707 (of the same, different, or combination of types) can be used according to particular needs, desires, or particular implementations of the computer 702 and the described functionality. While memory 707 is illustrated as an internal component of the computer 702, in alternative implementations, memory 707 can be external to the computer 702.

An application 708 can be an algorithmic software engine providing functionality according to particular needs, desires, or particular implementations of the computer 702 and the described functionality. For example, an application 708 can serve as one or more components, modules, or applications 708. Multiple applications 708 can be implemented on the computer 702. Each application 708 can be internal or external to the computer 702.

The computer 702 can also include a power supply 714. The power supply 714 can include a rechargeable or non-rechargeable battery that can be configured to be either user- or non-user-replaceable. In some implementations, the power supply 714 can include power-conversion and management circuits, including recharging, standby, and power management functionalities. In some implementations, the power-supply 714 can include a power plug to allow the computer 702 to be plugged into a wall socket or a power source to, for example, power the computer 702 or recharge a rechargeable battery.

There can be any number of computers 702 associated with, or external to, a computer system including computer 702, with each computer 702 communicating over network 730. Further, the terms “client”, “user”, and other appropriate terminology can be used interchangeably without departing from the scope of the present disclosure. Moreover, the present disclosure contemplates that many users can use one computer 702 and one user can use multiple computers 702.

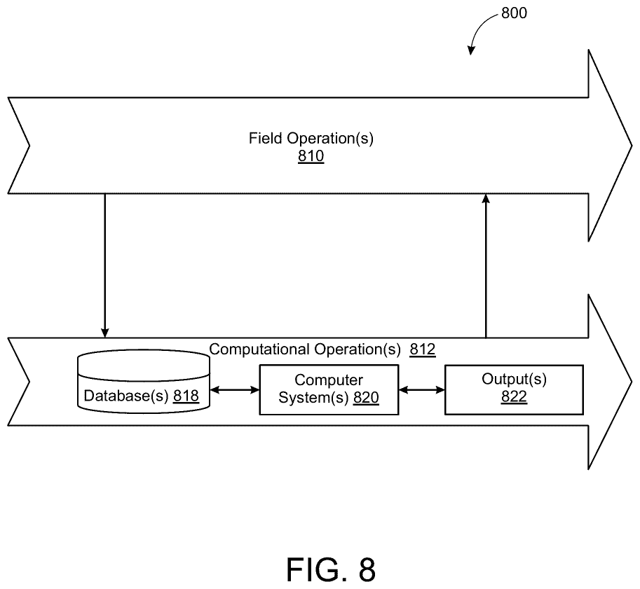

FIG. 8 illustrates hydrocarbon production operations 800 that include both one or more field operations 810 and one or more computational operations 812, which exchange information and control exploration for the production of hydrocarbons. In some implementations, outputs of techniques of the present disclosure can be performed before, during, or in combination with the hydrocarbon production operations 800, specifically, for example, either as field operations 810 or computational operations 812, or both.

Examples of field operations 810 include forming/drilling a wellbore, hydraulic fracturing, producing through the wellbore, injecting fluids (such as water) through the wellbore, to name a few. In some implementations, methods of the present disclosure can trigger or control the field operations 810. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 810 and responsively triggering the field operations 810 including, for example, generating plans and signals that provide feedback to and control physical components of the field operations 810. Alternatively or in addition, the field operations 810 can trigger the methods of the present disclosure. For example, implementing physical components (including, for example, hardware, such as sensors) deployed in the field operations 810 can generate plans and signals that can be provided as input or feedback (or both) to the methods of the present disclosure.

Examples of computational operations 812 include one or more computer systems 820 that include one or more processors and computer-readable media (e.g., non-transitory computer-readable media) operatively coupled to the one or more processors to execute computer operations to perform the methods of the present disclosure. The computational operations 812 can be implemented using one or more databases 818, which store data received from the field operations 810 and/or generated internally within the computational operations 812 (e.g., by implementing the methods of the present disclosure) or both. For example, the one or more computer systems 820 process inputs from the field operations 810 to assess conditions in the physical world, the outputs of which are stored in the databases 818. For example, seismic sensors of the field operations 810 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 812 where they are stored in the databases 818 and analyzed by the one or more computer systems 820.

In some implementations, one or more outputs 822 generated by the one or more computer systems 820 can be provided as feedback/input to the field operations 810 (either as direct input or stored in the databases 818). The field operations 810 can use the feedback/input to control physical components used to perform the field operations 810 in the real world.

For example, the computational operations 812 can process the seismic data to generate three-dimensional (3D) maps of the subsurface formation. The computational operations 812 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 812 to process new information about the formation and control the drilling to adjust to the observed conditions in real-time.

The one or more computer systems 820 can update the 3D maps of the subsurface formation as information from one exploration well is received and the computational operations 812 can adjust the location of the next exploration well based on the updated 3D maps. Similarly, the data received from production operations can be used by the computational operations 812 to control components of the production operations. For example, production well and pipeline data can be analyzed to predict slugging in pipelines leading to a refinery and the computational operations 812 can control machine operated valves upstream of the refinery to reduce the likelihood of plant disruptions that run the risk of taking the plant offline.

In some implementations of the computational operations 812, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

Implementations of the subject matter and the functional operations described in this specification can be implemented in digital electronic circuitry, in tangibly embodied computer software or firmware; in computer hardware, including the structures disclosed in this specification and their structural equivalents; or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus”, “computer”, and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus and special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, Linux, Unix, Windows, Mac OS, Android, or iOS.

A computer program, which can also be referred to or described as a program, software, a software application, a module, a software module, a script, or code can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document; in a single file dedicated to the program in question; or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes; the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks, optical memory devices, and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), or a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser. Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, or in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations; and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

### Embodiments

Embodiment 1: A computer-implemented method comprising: obtaining one or more wireline logs of a well interval in a hydrocarbon reservoir; applying a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and providing the determined one or more rock or fluid properties of the hydrocarbon reservoir to determine a volume of the hydrocarbon reservoir for exploration of the hydrocarbon reservoir.
Embodiment 2: The computer-implemented method of embodiment 1, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.
Embodiment 3: The computer-implemented method of embodiment 1 or 2, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.
Embodiment 4: The computer-implemented method of any one of embodiments 1 to 3, wherein the well interval is an unsampled well interval.
Embodiment 5: The computer-implemented method of any one of embodiments 1 to 4, further comprising: obtaining a plurality of wireline logs of a plurality of wells; obtaining a plurality of reservoir rock or fluid property measurements from samples of the plurality of wells; and determining the trained ML model by training a machine learning model using the plurality of wireline logs and the plurality of reservoir rock or fluid property measurements.
Embodiment 6: The computer-implemented method of embodiment 5, wherein the samples of the plurality of wells comprise at least one of core samples, plug samples, or thin section samples of the plurality of wells.
Embodiment 7: The computer-implemented method of embodiment 5 or 6, wherein determining the trained ML model comprises determining a plurality of learning parameters in the machine learning model.
Embodiment 8: The computer-implemented method of embodiment 7, wherein the plurality of learning parameters comprise at least one of a learning rate, a quantity of neurons, an activation function, or the set of weight factors.
Embodiment 9: The computer-implemented method of embodiment 8, wherein the activation function is a sigmoid function or a Gaussian function.
Embodiment 10: The computer-implemented method of any one of embodiments 1 to 9, wherein the trained ML model comprises an artificial neural network (ANN), a support vector machine (SVM), a regression tree (RT), a random forest (RF), an extreme learning machine (ELM), or a type I and type II fuzzy logic (TIFL/T2FL).
Embodiment 11: A non-transitory computer-readable medium storing one or more instructions executable by a computer system to perform operations comprising: obtaining one or more wireline logs of a well interval in a hydrocarbon reservoir; applying a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and providing the determined one or more rock or fluid properties of the hydrocarbon reservoir to determine a volume of the hydrocarbon reservoir for exploration of the hydrocarbon reservoir.
Embodiment 12: The non-transitory computer-readable medium of embodiment 11, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.
Embodiment 13: The non-transitory computer-readable medium of embodiment 11 or 12, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.
Embodiment 14: The non-transitory computer-readable medium of any one of embodiments 11 to 13, wherein the well interval is an unsampled well interval.
Embodiment 15: The non-transitory computer-readable medium of any one of embodiments 11 to 14, further comprising: obtaining a plurality of wireline logs of a plurality of wells; obtaining a plurality of reservoir rock or fluid property measurements from samples of the plurality of wells; and determining the trained ML model by training a machine learning model using the plurality of wireline logs and the plurality of reservoir rock or fluid property measurements.
Embodiment 16: A computer-implemented system, comprising one or more computers; and one or more computer memory devices interoperably coupled with the one or more computers and having tangible, non-transitory, machine-readable media storing one or more instructions that, when executed by the one or more computers, perform one or more operations comprising: obtaining one or more wireline logs of a well interval in a hydrocarbon reservoir; applying a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and providing the determined one or more rock or fluid properties of the hydrocarbon reservoir to determine a volume of the hydrocarbon reservoir for exploration of the hydrocarbon reservoir.
Embodiment 17: The computer-implemented system of embodiment 16, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.
Embodiment 18: The computer-implemented system of embodiment 16 or 17, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.
Embodiment 19: The computer-implemented system of any one of embodiments 16 to 18, wherein the well interval is an unsampled well interval.
Embodiment 20: The computer-implemented system of any one of embodiments 16 to 19, further comprising: obtaining a plurality of wireline logs of a plurality of wells; obtaining a plurality of reservoir rock or fluid property measurements from samples of the plurality of wells; and determining the trained ML model by training a machine learning model using the plurality of wireline logs and the plurality of reservoir rock or fluid property measurements.

We claim:

1. A computer-implemented method comprising:
obtaining, using at least one hardware processor, one or more wireline logs of a well interval in a hydrocarbon reservoir;
applying, using the at least one hardware processor, a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and
providing, using the at least one hardware processor, the determined one or more rock or fluid properties of the hydrocarbon reservoir to determine a volume of the hydrocarbon reservoir for exploration of the hydrocarbon reservoir.

2. The computer-implemented method of claim 1, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.

3. The computer-implemented method of claim 1, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.

4. The computer-implemented method of claim 1, wherein the well interval is an unsampled well interval.

5. The computer-implemented method of claim 1, further comprising:
obtaining a plurality of wireline logs of a plurality of wells;
obtaining a plurality of reservoir rock or fluid property measurements from samples of the plurality of wells; and
determining the trained ML model by training a machine learning model using the plurality of wireline logs and the plurality of reservoir rock or fluid property measurements.

6. The computer-implemented method of claim 5, wherein the samples of the plurality of wells comprise at least one of core samples, plug samples, or thin section samples of the plurality of wells.

7. The computer-implemented method of claim 5, wherein determining the trained ML model comprises determining a plurality of learning parameters in the machine learning model.

8. The computer-implemented method of claim 7, wherein the plurality of learning parameters comprise at least one of a learning rate, a quantity of neurons, an activation function, or the set of weight factors.

9. The computer-implemented method of claim 8, wherein the activation function is a sigmoid function or a Gaussian function.

10. The computer-implemented method of claim 1, wherein the trained ML model comprises an artificial neural network (ANN), a support vector machine (SVM), a regression tree (RT), a random forest (RF), an extreme learning machine (ELM), or a type I and type II fuzzy logic (T1FL/T2FL).

11. A non-transitory computer-readable medium storing one or more instructions executable by a computer system to perform operations comprising:
obtaining one or more wireline logs of a well interval in a hydrocarbon reservoir;
applying a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and
providing the determined one or more rock or fluid properties of the hydrocarbon reservoir to determine a volume of the hydrocarbon reservoir for exploration of the hydrocarbon reservoir.

12. The non-transitory computer-readable medium of claim 11, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.

13. The non-transitory computer-readable medium of claim 11, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.

14. The non-transitory computer-readable medium of claim 11, wherein the well interval is an unsampled well interval.

15. The non-transitory computer-readable medium of claim 11, further comprising:
obtaining a plurality of wireline logs of a plurality of wells;
obtaining a plurality of reservoir rock or fluid property measurements from samples of the plurality of wells; and
determining the trained ML model by training a machine learning model using the plurality of wireline logs and the plurality of reservoir rock or fluid property measurements.

16. A computer-implemented system comprising:
one or more computers; and
one or more computer memory devices interoperably coupled with the one or more computers and having tangible, non-transitory, machine-readable media storing one or more instructions that, when executed by the one or more computers, cause the computer-implemented system to perform one or more operations comprising:
obtaining one or more wireline logs of a well interval in a hydrocarbon reservoir;
applying a trained machine learning (ML) model to the one or more wireline logs of the well interval to upscale one or more rock or fluid properties of the hydrocarbon reservoir to a borehole scale, wherein the trained ML model comprises a set of weight factors, and wherein applying the trained ML model to the one or more wireline logs comprises applying the set of weight factors to the one or more wireline logs to determine the one or more rock or fluid properties of the hydrocarbon reservoir at the borehole scale; and
providing the determined one or more rock or fluid properties of the hydrocarbon reservoir to determine a volume of the hydrocarbon reservoir for exploration of the hydrocarbon reservoir.

17. The computer-implemented system of claim 16, wherein the one or more wireline logs comprise at least one of gamma ray (GR) log, neutron porosity (NPHI) log, density (RHOB) log, spontaneous potential (SP) log, resistivity (RES) log, sonic compression (DTC) log, or sonic shear (DTS) log.

18. The computer-implemented system of claim 16, wherein the one or more rock or fluid properties comprise at least one of cementation factor, porosity, permeability, grain size, grain density, gas-oil ratio (GOR), API, capillary pressure, wettability, saturation index, tortuosity, Young modulus, Poisson's ratio, mineralogy, rock types, fluid types, pore types, depositional environment, or diagenetic facies.

19. The computer-implemented system of claim 16, wherein the well interval is an unsampled well interval.

20. The computer-implemented system of claim 16, further comprising:
obtaining a plurality of wireline logs of a plurality of wells;
obtaining a plurality of reservoir rock or fluid property measurements from samples of the plurality of wells; and
determining the trained ML model by training a machine learning model using the plurality of wireline logs and the plurality of reservoir rock or fluid property measurements.
